(19) United States
(12) Patent Application Publication
(10) Pub. No.: US 2011/0308573 A1
(43) Pub. Date: Dec. 22, 2011

(54) DEVICES AND METHODS TO CREATE A DIFFUSE REFLECTION SURFACE

(75) Inventor: Joachim Jaus, Freiburg (DE)

(73) Assignee: Fraunhofer USA, Inc. Center for Sustainable Energy Systems, Cambridge, MA (US)

(21) Appl. No.: 13/165,069

(22) Filed: Jun. 21, 2011

Related U.S. Application Data
(60) Provisional application No. 61/356,742, filed on Jun. 21, 2010.

(51) Int. Cl. H01L 31/052; H01L 31/18

(52) U.S. Cl. 136/246; 438/72; 257/E31.128

(57) ABSTRACT

A photovoltaic module includes a plurality of solar cells, each solar cell having an active front side and a back side. A busbar is provided and has a first portion that is electrically connected to an active front side of a first solar cell, and a second portion that is electrically connected to a back side of a second solar cell. At least a front side of the first portion of the busbar includes a diffuse reflective coating.

### RELATED APPLICATIONS

This application claims priority to U.S. Provisional Patent Application No. 61/356,742, entitled Devices and Methods to Create a Diffuse Reflection Surface, and filed on Jun. 21, 2010, which application is incorporated herein in its entirety.

### FIELD

Exemplary embodiments of the present invention relate to providing a diffuse reflective surface on inactive materials within photovoltaic modules.

### BACKGROUND

Photovoltaic modules known in the prior art depend on an active material, such as silicon, to create an electrical current when exposed to light energy. These modules also contain certain inactive materials used to hold the active material and collect the current created. The amount of energy created depends in large part on the area of active material that is exposed to the light energy source. Accordingly, photovoltaic module designers try to minimize the area of inactive material in a module.

The market for photovoltaic modules is dominated by those made of crystalline silicon solar cells. These cells use a crystalline silicon wafer and surface coating that are appropriately doped to create a p-n junction below the surface of the wafer. This geometry results in electrical contacts on the top (light source facing) and bottom surfaces of the crystalline silicon solar cell. A full-area metal contact is usually formed on the bottom surface of the cell and a grid-like contact made up of fine fingers and larger transverse members is formed on the top surface.

Though a photovoltaic module may consist of just one cell, they are predominantly composed of a plurality of solar cells. These cells are typically linked together in a series electrical connection (i.e., positive terminal of one cell to negative terminal of the next cell) by a metallic wire in a process known as “tabbing and stringing.” Because silicon solar cells have terminals on their top and bottom surfaces, the tabbing and stringing process requires soldering the tabbing wire to one surface (e.g., the top, along the transverse members) of one solar cell and then the opposite surface (e.g., the bottom, along the bottom metal contact) of the adjacent solar cell. After a string of solar cells has been soldered in this manner, it is connected to other strings in a series or parallel electrical connection. The strings are then encapsulated in or attached to a protective plastic and/or glass layer to create the finished photovoltaic module. Commonly used polymers (e.g., ethylene vinyl acetate, or EVA) and glasses each have a refractive index of approximately 1.5 (1.1-3.0). Certain modules may omit either the plastic or glass protective layer, but at least one protective layer is needed to shield the solar cells from environmental conditions such as rain, dust, hail, and mechanical forces.

One problem faced in the prior art is that the tabbing wire soldered to the transverse members along the top of a solar cell, referred to as busbar, reduces the area of active material exposed to light energy. In common designs used today, 1-5% of a solar cell is covered by busbar. Worse still, the busbar reflects light impinging on it back out of the photovoltaic module. This is because the soldering process leaves the busbar with a surface that has a reflection profile dominated by specular reflection, where light leaves the reflective surface at the same angle in which it approached. FIG. 1 illustrates a prior art photovoltaic module and the specular reflection profile of the busbar. In the typical photovoltaic module illustrated in FIG. 1, almost all the light impinging on the busbar is reflected back out of the cell, except for a minor internal reflection at the glass-air interface. This reflected energy is lost, resulting in an efficiency reduction in the same order of magnitude as the area covered by the busbar or other inactive material, i.e., a reduction of about 1-5% in today's commonly used designs.

There have been various attempts in the prior art to recapture this reflected energy, but all of them have significant drawbacks. Various techniques of altering the busbar shape or modifying other components of the photovoltaic module have significantly complicated the manufacturing process and added cost to the product without being sufficiently effective at recapturing the reflected light. As such, a need exists for a better way to recapture reflected light from inactive materials, such as busbar, in a photovoltaic module.

### SUMMARY

The present invention includes devices and methods that alter the specular reflection profile of inactive areas in a photovoltaic module, such as busbar, to a diffuse reflection profile. The inactive areas then exhibit isotropic luminance and a substantial portion of impinging light rays are reflected at angles where total internal reflection at the glass-air interface directs them back on to an active area of the photovoltaic module. As a result, the efficiency of the photovoltaic module is increased.

In its first aspect, the invention includes a photovoltaic module having one or more silicon solar cells. The silicon solar cells feature one or more active and inactive areas. The active areas are made of a silicon semiconductor material and create current when exposed to light energy. The inactive areas include features such as current conducting fingers and busbars. The inactive areas in the silicon solar cells have a diffuse reflective coating applied to impart a diffuse reflection profile.

### BRIEF DESCRIPTION OF THE DRAWINGS

FIG. 1 is a schematic representation of the reflection profile in a prior art photovoltaic module, showing the predominantly specular reflection profile and loss of reflected energy;

FIG. 2a is a schematic representation of a solar cell, including active material, conducting fingers, transverse members, and tabbing wire;

FIG. 2b is a schematic representation showing two solar cells strung together by the tabbing and stringing process;

FIG. 3 is a schematic representation of the reflection profile of a photovoltaic module of the present invention, showing the diffuse reflection profile, total internal reflection of many rays, and subsequent recapture of reflected energy;

FIG. 4 is a schematic representation of a preferred embodiment of the present invention, showing a coating of titanium oxide particles in a transparent filler and the diffraction of light as it passes through the material;

FIG. 5a is a schematic and photographic representation of the laser demonstration example, the schematic illustrates the behavior of light reflecting from the prior art photovoltaic module and the photograph shows actual reflection results; and

FIG. 5b is a schematic and photographic representation of the laser demonstration example, the schematic illustrates the behavior of light reflecting from a photovoltaic module of the present invention and the photograph shows actual reflection results.

### DETAILED DESCRIPTION OF THE INVENTION

The present invention provides devices and methods to alter the specular reflection profile of inactive areas in a photovoltaic module to a diffuse reflection profile, thereby recapturing lost energy and increasing the efficiency of the module. The present invention encompasses various coatings, depositions, and surface alterations that alter the reflection profile of the inactive material.

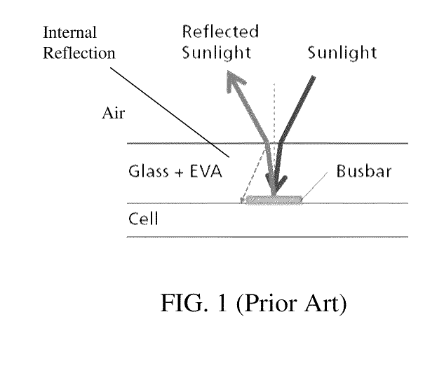

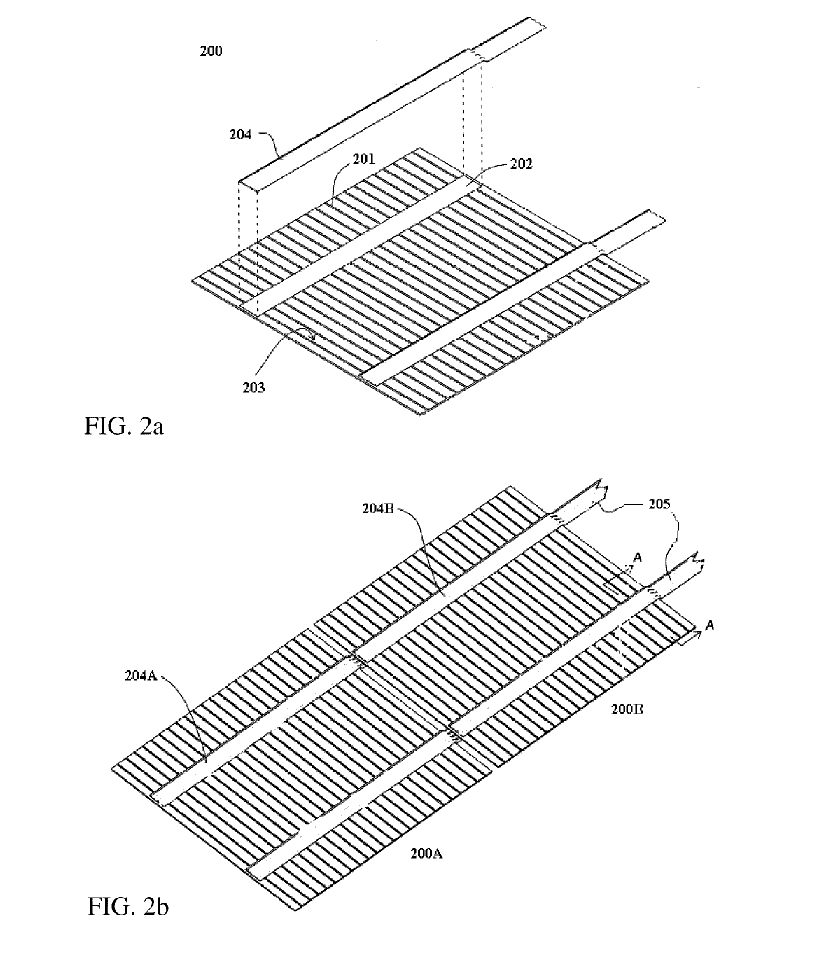

FIGS. 1-2 illustrate a state of the art silicon solar cell and the predominately specular reflection profile of its inactive areas. FIG. 2a illustrates a single silicon solar cell 200. The cell 200 contains inactive areas known as fingers 201 and larger transverse members 202. These features are commonly applied using a screen printing process with silver inks. The fingers 201 run across the cell 200 perpendicular to the transverse members 202 and serve to collect current from the cell's active area 203 (i.e., the silicon semiconductor wafer). The fingers 201 provide a conductive path to the transverse members 202, which are used as electrical contacts for the cell 200.

In the tabbing and stringing process described above, tabbing wire or ribbon 204 is soldered to the cell 200 along the transverse members 202. The soldered ribbon on top of the cell is referred to as busbar. The cells are then strung together by soldering the tabbing wire 204 to an adjacent silicon solar cell. To achieve the series electrical connection commonly used to connect multiple solar cells, the tabbing wire 204 must connect the top of one cell to the bottom of the next cell. Such an arrangement of two adjacent cells is illustrated in FIG. 2b.

In FIG. 2b, silicon solar cell 200A is connected to cell 200B by the tabbing and stringing process. The tabbing wires 204A visible on the top of the first cell 200A dip underneath the adjacent cell 200B and are soldered to the bottom thereof. Tabbing wires 204B visible on top of the second cell 200B are shown with exposed ends 205 that are ready to be soldered to the bottom of another solar cell. Repeating the process creates a string of silicon solar cells that can then be combined to create a photovoltaic module.

The soldering process used in connecting adjacent solar cells results in a smooth busbar surface that exhibits a predominately specular reflection profile. As discussed above, FIG. 1 illustrates this reflection profile in a state of the art photovoltaic module having silicon solar cells like that of FIG. 2. Specular reflection profiles are characterized by the law of reflection, which states that light reflects off a surface at the same angle to the surface normal as it impinges. Because photovoltaic modules are typically pointed in the general direction of the light source, light typically impinges on the module at a small angle from the normal. The resulting reflection, then, is also at a small angle from the normal. This angle is typically less than the approximately 42 degree critical angle necessary for total internal reflection with a glass-air interface. The critical angle for total internal reflection is computed using Snell's law of refraction with the refractive index of air (1.0) and glass (˜1.5). Because the reflection angle is typically less than 42 degrees from the normal, most of the reflected light is able to exit the module and does not contribute to the creation of electrical current.

The devices and methods of the present invention alter the specular reflection profile of the busbars and other inactive areas in the silicon solar cell in order to recapture the reflected energy. Inactive areas in solar cells of the present invention exhibit a diffuse reflection profile. Diffuse reflective materials have an energy distribution characterized by a Lambertian distribution, where incoming light is distributed evenly in all directions (also known as isotropic luminance).

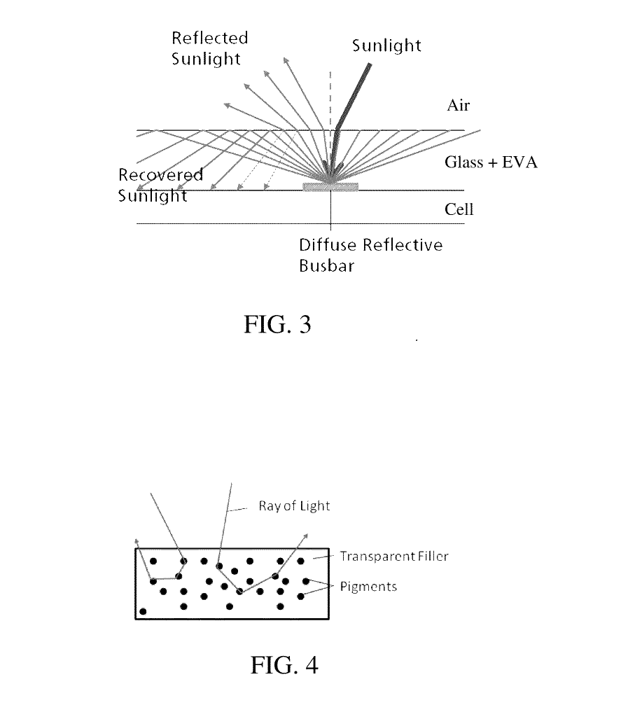

FIG. 3 illustrates the reflection profile of a photovoltaic module of the present invention showing isotropic luminance. Despite the fact that the light source impinges at a small angle from the normal, the busbar reflects the light in all directions. While some light does still reflect at angles small enough to allow refraction and exit from the cell, a great deal of light is reflected at large enough angles that total internal reflection at the glass-air interface redirects the light back onto the cell's active area. As mentioned above, most polymers and glasses commonly used in silicon solar cell manufacture have a refractive index of about 1.5 (the refractive index of air is 1.0). This means the critical angle above which total internal reflection occurs is approximately 42 degrees from the normal. Furthermore, for light impinging at lower angles, the increased Fresnel reflection at the glass-air interface leads to more light being redirected back to the solar cell as compared to the standard specular reflective busbar.

A preferred embodiment for providing this diffuse reflection profile is the application of a coating on the busbar that alters its reflective properties. The use of a coating is desirable because it can be easily applied in the manufacturing process with minimal cost.

A preferred coating material is a white paint applied to the finished busbar. An example of such a paint is a suspension of titanium oxide particles in a transparent filler polymer. This kind of coating is effective because the highly refractive particles cause the light to change direction many times as it passes through the coating. FIG. 4 illustrates how light travels through this type of coating and is scattered at various angles. The titanium oxide particles have a high refractive index of about 2.7 and are smaller than the wavelength of light. The transparent filler polymer preferably has a refractive index of at least about 1.5. Light impinging on the coating diffracts several times as it passes through and out of the coating. The multiple diffractions create the diffuse reflection profile observed in FIG. 3.

The filler material in the coating can be any material capable of holding particles such as the titanium oxide mentioned above. One example of a solution containing titanium dioxide particles is everyday white-out or correction fluid. Widely used coating solutions like this are preferred because they are readily available.

Similarly, titanium oxide particles are just one example of a suitable particle for use in a diffuse reflective coating. To provide a high level of diffraction, suspended particles should have a high refractive index and be smaller than the wavelength of light. In preferred embodiments, the refractive index of the particles can be at least approximately 1.7, at least approximately 2.0, at least approximately 2.7, greater than the refractive index of the transparent filler material, or mixtures of such particles. Particle sizes between about 20 and 800 nanometers are preferred. Examples of suitable particles include titanium dioxide, silicon dioxide, and silicon nitride. The particle density in the solution need not fall in a specific range, but must be high enough to provide coverage over the application area. Inexpensive materials are favored to reduce the cost of the coating material.

One of skill in the art will appreciate that several other combinations of small particles with high refractive indices and filler materials can be combined in a coating that creates a diffuse reflection profile. Such combinations are within the scope of the present invention.

Another preferred embodiment of the invention is an engineered material that is designed to minimize the amount of low-angle reflections in the reflection profile. This type of behavior is the opposite of retro-reflective materials such as Scotchlite®. Such a reduction in low-angle reflection will result in even more of the reflected light being recaptured to create electrical current. To create the engineered material, nano-scale particles would be engineered in the correct size range and with the correct refractive index then suspended in a filler polymer. With the correctly sized particles present in the coating, the amount of diffraction can be maximized resulting in more high angle reflection.

One of skill in the art will appreciate that when using any of the coatings discussed herein, the invention's usefulness is not limited to only the busbar area of a silicon solar cell. Any of the coatings could be applied to all of the inactive areas in the silicon solar cell and photovoltaic module, including the busbars, fingers, current collecting wires, or any other area not covered by the active silicon semiconductor material. For certain materials, such as screen-printed fingers, the coating may not be necessary due to the rough texture left by the screen-printing process. The coating would be effective, however, on any component that is evaporated, ink jetted, plated, or manufactured in any other way that results in a smooth surface with predominately specular reflection.

The use of a diffuse reflective coating is preferred because of the ease and flexibility in application during the manufacturing process. The coating could be applied to the busbars on the silicon solar cell or to the tabbing wire before soldering to the cell. If the coating is applied before soldering to the cell, there is a possibility that the coating could interfere with the electrical connection created by the soldering process. This can be avoided by using a coating that is electrically conductive. However, electrically conductive coatings are often expensive and therefore undesirable for large scale manufacturing. A preferred way to prevent interference is to exclude certain areas from the application process to preserve a clean metal surface for soldering.

In cases where the coating is applied after soldering, steps must be taken to prevent the application of the coating to active areas of the silicon solar cell. This can be accomplished through a masking process that protects areas from receiving the coating. Alternatively, a computer controlled or vision-based system may be employed to follow the path of the busbars on the solar cell and apply the coating only along the busbars or other inactive areas.

A preferred method of application is by ink jet printing the coating on to the busbars. Ink jet printing can be conducted before or after soldering the tabbing wire to the cells. If done before application to the cells, the tabbing wire can be masked to preserve a clean area for soldering. In some cases, masking may not be required because the ink jetting process can be sufficiently controlled to avoid coating the soldering surface. If ink jet printing is used after soldering has taken place, active areas of the solar cell can be masked to avoid receiving the coating. In this case as well, masking may not always be necessary if the ink jet printing process can be precisely controlled to avoid application to the active areas of the solar cell.

A second method of application is by dipping the busbars into a bath of the coating. Masking the active areas of the solar cell would protect them from receiving the coating when dipped. The tabbing wire could also be dipped before application to the cells, and an area could be masked if necessary to protect a clean surface for soldering.

Another method of application is by aerosol deposition of the coating. To accomplish this, active areas of the solar cell could be masked and then the coating could be sprayed on from above the cell. Alternatively, the tabbing wire could be sprayed prior to being soldered onto the cells.

Roll coating is a third method of application for a diffuse reflective coating. This application method would require a specifically guided (e.g., vision-guided) application device to spread the paint over the surface of the busbars and other inactive areas.

Alternatively, the coating could be deposited on the busbars in a powder coating or electroplating process. In a powder coating deposition process, a powder form of the coating could be sprayed on to the busbars and then heated to cement in place. This deposition process could also take place either before or after soldering to the solar cells, but appropriate masking may be necessary. In the case where deposition takes place after soldering, it will most likely be necessary to mask the active areas of the solar cell.

In an electrodeposition process, particles of the coating could be applied to the busbars using an electrical current and an electrolyte bath. Again, appropriate masking of the tabbing wires or active areas in a silicon solar cell would be necessary depending on whether the coating is applied before or after the tabbing wires are soldered to the cells.

In the case of electrodeposition or powder coating, it may be possible to directly apply the refractive particles without the need for a filler polymer. Particle size and composition will be especially important with these application techniques, and certain sizes or materials may not be suitable for application in these manners.

A second preferred embodiment of the present invention involves altering the surface reflective properties of the busbars themselves rather than applying a diffuse reflective coating. This approach is more similar to what has been explored in the prior art, but the present invention results in a far more diffusely reflective surface than has been achieved in the past.

The specular reflection profile of the busbars and other inactive areas in a solar cell is predominately the result of their smooth surface texture. This is the reason a diffuse reflective coating is often not necessary on solar cell fingers; the screen printing process commonly used to deposit them on the cell leaves a roughly textured surface that already has a diffuse reflection profile.

In this embodiment, any of several deformation processes can be used to roughen the surface texture of the busbars and provide a highly diffuse reflection profile. Alteration of the busbar surface in this embodiment must occur after soldering to the solar cells because it is the soldering process that results in a smooth busbar surface. Given that many of the example roughening processes below use caustic or abrasive agents, masking of the nearby active areas is recommended.

One example of these processes is mechanical or chemical etching of the busbar material. When applied, etching agents cut into the smooth surface and leave it with an uneven texture. Similarly, the material's surface could be altered abrasively through sandblasting. Pressure imprinting could also roughen the surface by pressing the busbar material with a textured mold. Finally, the busbar surface could be altered by laser ablation or other laser patterning technique. Laser roughening is advantageous because it can be precisely targeted, potentially eliminating the need for masking adjacent areas of the cell. All of these techniques result in a busbar with a roughened surface texture and diffuse reflection profile.

### EXAMPLE OF COLLIMATED LASER & CAMERA

The present invention can be demonstrated by comparing the reflection profiles of two photovoltaic modules, one with a diffuse reflective busbar and one without. The photovoltaic modules used were both manufactured using the same process. They consist of one monocrystalline silicon solar cell with two buswires on both the front and back side. The cells are embedded between two ethylene vinyl acetate (EVA) sheets and laminated to a sheet of 4 mm low-iron front glass. In use, the measured difference in short circuit current between these samples was between 0.6 and 1%.

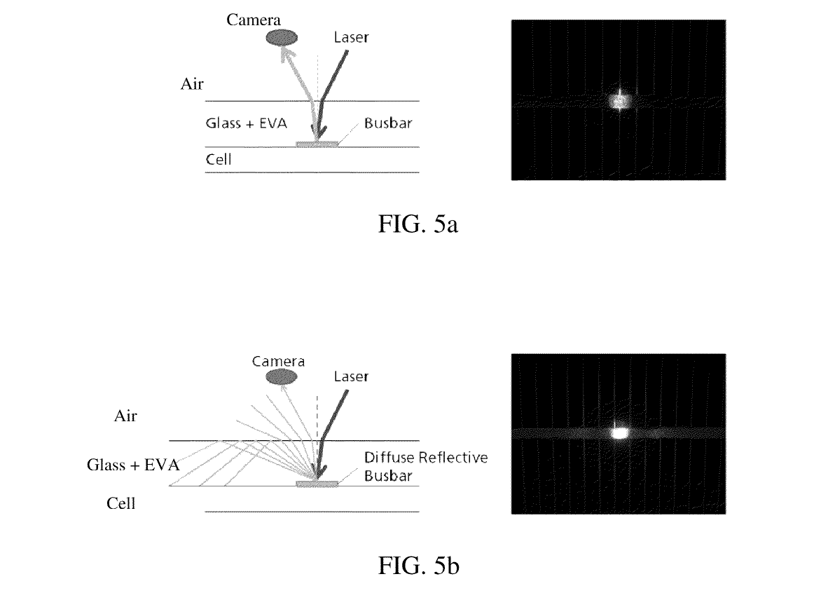

The difference can be visualized by aiming a collimated laser at the busbar and using a camera to view the laser's reflection from above the module. The example setup for these photovoltaic modules is illustrated in FIG. 5.

In FIG. 5a, the laser is directed at the prior art busbar. Because the busbar's reflection profile is dominated by specular reflection, the laser's light reflects off the busbar and exits the photovoltaic module at the same angle it entered. As a result, only a single bright spot is seen in the camera image on the right of FIG. 5a.

FIG. 5b illustrates the diffuse reflective busbar of the present invention. When the collimated laser is aimed at the busbar, the reflection profile is diffuse with light reflecting in a variety of angles. As a result, a large portion of the reflected light is redirected back onto the photovoltaic module because of total internal reflection at the glass-air interface. In the camera image on the right of FIG. 5b, a bright ring is visible surrounding the central bright spot. This ring is light reflected back onto the module by total internal reflection. There is also a darker ring in between the bright central spot and illuminated outer ring. This is the result of light reflected at less than the critical angle necessary for total internal reflection. Light that would illuminate this space is instead exiting the module in the same way most all the light exits the module in FIG. 5a. However, some light still does reach this area through Fresnel reflections and multiple internal reflections.

Thus, the additional lighted areas in the solar cell of FIG. 5b represent the recaptured light energy being used by the silicon semiconductor material to create electrical current. Comparing the picture in FIG. 5b with that of FIG. 5a shows the significant effect of the diffuse reflective busbar surface.

A person of ordinary skill in the art will appreciate further features and advantages of the invention based on the above-described embodiments. Accordingly, the invention is not to be limited by what has been particularly shown and described, except as indicated by the appended claims or those ultimately provided. The invention expressly includes all combinations and sub-combinations of features included above.

1. A photovoltaic module comprising:
a plurality of solar cells, each solar cell having an active front side and a back side; and
a busbar having a first portion that is electrically connected to an active front side of a first solar cell, and a second portion that is electrically connected to a back side of a second solar cell;
wherein at least a front side of the first portion of the busbar includes a diffuse reflective coating.

2. A photovoltaic module according to claim 1, wherein the diffuse reflective coating includes a transparent filler having suspended high refractive index particles.

3. A photovoltaic module according to claim 2, wherein the high refractive index particles have a refractive index of at least approximately 1.7.

4. A photovoltaic module according to claim 2, wherein the high refractive index particles have a refractive index of at least approximately 2.0.

5. A photovoltaic module according to claim 2, wherein the high refractive index particles have a refractive index of at least approximately 2.7.

6. A photovoltaic module according to claim 2, wherein the high refractive index particles have a size of between about 20 and 800 nanometers.

7. A photovoltaic module according to claim 6, wherein the high refractive index particles comprise titanium oxide.

8. A photovoltaic module according to claim 2, wherein the transparent filler has a refractive index of at least approximately 1.5.

9. A photovoltaic module according to claim 8, wherein the high refractive index particles have a refractive index that is greater than the refractive index of the transparent filler.

10. A photovoltaic module according to claim 1, wherein the busbar has a front side and a back side, the back side of the first portion being electrically connected to the front side of the first solar cell and the front side of the second portion being electrically connected to the back side of the second solar cell, wherein the front side of the second portion does not have a diffuse reflective coating.

11. A method of manufacturing a photovoltaic module having a plurality of solar cells, each solar cell having an active front side and a back side, and a busbar having a first portion that is electrically connected to an active front side of a first solar cell, and a second portion that is electrically connected to a back side of a second solar cell, wherein at least a front side of the first portion of the busbar presents a diffuse reflective surface, the method comprising:
electrically connecting a back side of the first portion of the busbar to the front side of the first solar cell;
electrically connecting the front side of the second portion of the busbar to the back side of the second solar cell; and
applying a treatment to the front side of the first portion of the busbar to create a diffuse reflective surface.

12. The method of claim 11, wherein the treatment applied to the front side of the first portion of the busbar is an application of a diffuse reflective coating.

13. The method of claim 12, wherein the diffuse reflective coating is not applied to the front side of the second portion of the busbar.

14. The method of claim 13, wherein the diffuse reflective coating is applied to the busbar before electrical connection of the busbar to the first and second solar cells.

15. The method of claim 13, wherein the diffuse reflective coating is applied to the busbar after electrical connection of the busbar to the first and second solar cells.

16. The method of claim 11, wherein the diffuse reflective coating includes a transparent filler having high refractive index particles.

17. The method of claim 16, wherein the diffuse reflective coating is applied using ink jet printing.

18. The method of claim 16, wherein the diffuse reflective coating is applied using aerosol deposition.

19. The method of claim 16, wherein the diffuse reflective coating is applied by dipping a masked busbar in the coating.

20. The method of claim 11, wherein the application of a treatment includes applying a roughening process to the front side of the first portion of the busbar.
